(19) United States
(12) Patent Application Publication
(10) Pub. No.: US 2026/0171699 A1
(43) Pub. Date: Jun. 18, 2026

(54) METHODS AND SYSTEMS TO INTERFACE BETWEEN VEHICLES AND CELLULAR MODEMS

(71) Applicant: United Radio, Inc., East Syracuse, NY (US)

(72) Inventor: Corey Martino, Liverpool, NY (US)

(73) Assignee: United Radio, Inc., East Syracuse, NY (US)

(21) Appl. No.: 18/985,439

(22) Filed: Dec. 18, 2024

(51) Int. Cl. H01R 12/72; H01R 13/02; H05K 1/02

(52) U.S. Cl. CPC H01R 12/724; H01R 13/025; H05K 1/0213; H05K 2201/10106

(57) ABSTRACT

A in-vehicle communication device, comprising: a signal input interface configured to receive a plurality of different vehicle indication signals; an N-channel MOSFET bank in communication with the signal input interface and comprising a plurality of N-channel MOSFETs; a plurality of LEDs in communication with a respective one of the plurality of different vehicle indication signals; and a signal output interface configured to receive an output signal from the N-channel MOSFET bank and communicate the output signal to a communications interface of a wireless communication device, wherein the signal output interface is configured to communicate the output signal to the communications interface of the wireless communication device.

### FIELD OF THE INVENTION

The present invention relates to devices and systems for interfacing between a vehicle and a cellular modem, and more specifically to an in-vehicle communication device configured to interface between a vehicle and a cellular modem.

### BACKGROUND

Efficient emergency response is critical for saving lives and minimizing property damage during emergencies such as fires, medical crises, or natural disasters. Emergency vehicles, including ambulances, fire trucks, and police vehicles, often face delays due to traffic congestion, particularly at intersections controlled by traditional traffic lights. These delays not only hinder response times but can also compromise the safety of both emergency responders and other road users.

Traditional solutions to this problem, such as preemption systems that allow emergency vehicles to override traffic lights, typically rely on line-of-sight communication methods. These include infrared (IR) or radio frequency (RF) transmitters mounted on emergency vehicles and corresponding receivers installed at traffic lights. While effective in certain scenarios, these systems face significant limitations. For instance, they require direct visibility, are prone to interference, and lack the ability to dynamically adjust traffic conditions across a broader network.

With the advancement of cloud computing and real-time data transmission technologies, there is a growing potential to overcome these limitations through centralized, cloud-based communication systems. By integrating cloud infrastructure with GPS-equipped emergency vehicles and internet-connected traffic lights, a coordinated, intelligent system can be developed to dynamically manage traffic flow, prioritize emergency vehicles, and optimize safety and efficiency.

To utilize these cloud-based communication systems, emergency vehicles must be equipped with cellular modems that wirelessly communicate vehicle information to the cloud. Accordingly, the emergency vehicle must comprise an interface between the vehicle information (i.e., signals generated by the vehicle) and the cellular modem. Current interfaces are expensive, clunky, and difficult to install.

### SUMMARY OF THE INVENTION

Accordingly, there is a continued need for improved vehicle interfaces. Various embodiments and implementations herein are directed to an in-vehicle communication device configured to interface between a vehicle and a cellular modem. The device includes a signal input interface configured to receive different vehicle indication signals each indicative of a status of the vehicle. The device also includes an N-channel MOSFET bank in communication with the signal input interface and comprising N-channel MOSFETs, each of the N-channel MOSFETs connected to a vehicle indication signal, wherein an N-channel MOSFET is configured to generate an output signal in response to receiving a vehicle indication signal. The device comprises a plurality of LEDs in communication with a respective one of the vehicle indication signals, wherein each LED is configured to activate in response to receiving a vehicle indication signal. The device further includes a P-Channel MOSFET connected to a vehicle park indication signal, the vehicle park indication signal indicative that the vehicle is or is not in park. The device comprises a signal output interface configured to receive an output signal from the N-channel MOSFET bank and communicate the output signal to a communications interface of a wireless communication device.

According to an embodiment, the in-vehicle communication device provides a novel method for emergency vehicle communication with traffic light systems using a cloud-based architecture. The system enables seamless, real-time coordination across entire transportation networks, regardless of line-of-sight constraints or localized interference, thereby significantly improving emergency response effectiveness and public safety.

Generally, in one aspect, an in-vehicle communication device is provided. The device includes: a power connect; a ground connect; a signal input interface configured to receive a plurality of different vehicle indication signals, each of the plurality of vehicle indication signals indicative of a status of a vehicle; an N-channel MOSFET bank in communication with the signal input interface and comprising a plurality of N-channel MOSFETs, each of the plurality of N-channel MOSFETs connected to a respective one of the plurality of different vehicle indication signals, wherein each of the plurality of N-channel MOSFETs is configured to generate an output signal in response to receiving a vehicle indication signal; a plurality of LEDs, each of the plurality of LEDs in communication with a respective one of the plurality of different vehicle indication signals, wherein each of the plurality of LEDs is configured to activate in response to receiving a vehicle indication signal; and a signal output interface configured to receive an output signal from the N-channel MOSFET bank and communicate the output signal to a communications interface of a wireless communication device, wherein the signal output interface is configured to communicate the output signal to the communications interface of the wireless communication device.

According to an embodiment, the system includes a P-Channel MOSFET connected to a vehicle park indication signal, the vehicle park indication signal indicative that the vehicle is or is not in park, wherein the P-Channel MOSFET is configured to generate an activation signal when the park indication signal indicates that the vehicle is not in park.

According to an embodiment, the signal output interface is configured to receive the activation signal from the P-Channel MOSFET.

According to an embodiment, the plurality of different vehicle indication signals comprise one or more of a left turn indication signal, a right turn indication signal, an ignition signal, and a lightbar indication signal.

According to an embodiment, the plurality of LEDs comprise one or more of a power LED, a left turn indication signal LED, a right turn indication signal LED, an ignition signal LED, a lightbar indication signal LED, and a park LED.

According to an embodiment, the signal output interface is configured to communicate the output signal to the communications interface of the wireless communication device only when there is the activation signal from the P-Channel MOSFET.

According to an embodiment, the in-vehicle communication device further includes a housing configured to at least partially house at least the signal input interface, the N-channel MOSFET bank, the plurality of LEDs, the P-Channel MOSFET, and the signal output interface, wherein the housing comprises an opening to communicate an activated LED.

According to an embodiment, the wireless communication device is a modem.

According to an embodiment, the in-vehicle communication device further includes a plurality of voltage regulators each configured to: (1) receive an output signal from the N-channel MOSFET bank; (ii) convert the received output signal to an LED input signal for a respective one of the plurality of LEDs; and (iii) communicate the LED input signal to the respective one of the plurality of LEDs. According to an embodiment, each of the plurality of voltage regulators converts the received output signal to a 3-volt LED input signal.

According to an embodiment, the in-vehicle communication device further includes a park switch configured to adjust between a negative vehicle park indication signal and a positive vehicle park indication signal for the P-Channel MOSFET.

These and other aspects of the invention will be apparent from reference to the embodiments described hereinafter.

### BRIEF DESCRIPTION OF THE DRAWINGS

The present invention will be more fully understood and appreciated by reading the following Detailed Description in conjunction with the accompanying drawings, in which:

FIG. 1 is a schematic representation of an in-vehicle communication device, in accordance with an embodiment.

FIG. 2 is a schematic representation of an in-vehicle communication device, in accordance with an embodiment.

FIG. 3 is a schematic representation of an in-vehicle communication device, in accordance with an embodiment.

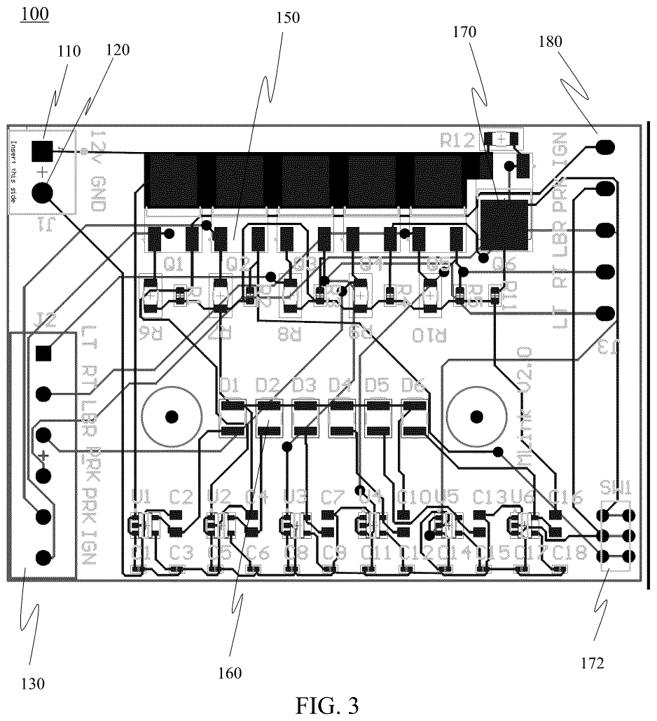

### DETAILED DESCRIPTION

The present disclosure describes various embodiments of a device and system configured for communication between a vehicle and a cellular modem. More generally, Applicant has recognized and appreciated that it would be beneficial to provide an improved in-vehicle communication device. Accordingly, an in-vehicle communication device includes a signal input interface configured to receive different vehicle indication signals each indicative of a status of the vehicle. The device also includes an N-channel MOSFET bank in communication with the signal input interface and comprising N-channel MOSFETs, each of the N-channel MOSFETs connected to a vehicle indication signal, wherein an N-channel MOSFET is configured to generate an output signal in response to receiving a vehicle indication signal. The device comprises a plurality of LEDs in communication with a respective one of the vehicle indication signals, wherein each LED is configured to activate in response to receiving a vehicle indication signal. The device further includes a P-Channel MOSFET connected to a vehicle park indication signal, the vehicle park indication signal indicative that the vehicle is or is not in park. The device comprises a signal output interface configured to receive an output signal from the N-channel MOSFET bank and communicate the output signal to a communications interface of a wireless communication device.

According to an embodiment, the devices and systems described or otherwise envisioned herein can, in some non-limiting embodiments, be implemented as a component of an emergency vehicle to communicate with a cloud infrastructure to control internet-connected traffic lights. However, the disclosure is not limited to these devices or systems, and thus the disclosure and embodiments disclosed herein can encompass any system that may utilize or benefit from the analysis described or otherwise envisioned herein.

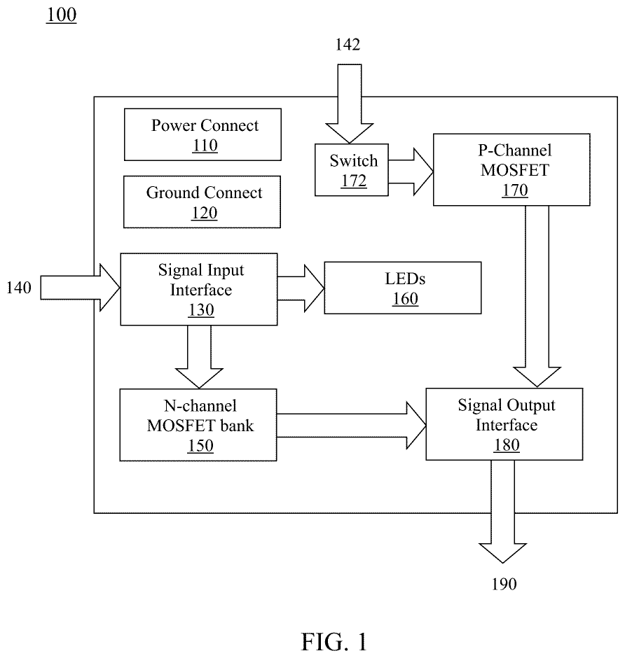

Referring to FIG. 1, in one embodiment, is a schematic representation of an in-vehicle communication device 100 configured to interface between a vehicle and a cellular modem. The devices and systems described in connection with the figures are provided as examples only, and shall be understood to not limit the scope of the disclosure. The in-vehicle communication device can be any of the systems or devices described or otherwise envisioned herein. The in-vehicle communication device can be a single device or multiple devices.

According to an embodiment, the in-vehicle communication device 100 comprises a power connect 110. The power connect can be any connection between the in-vehicle communication device and a power source (not shown), configured to provide power from the power source to the in-vehicle communication device. The power source can be any power source capable of providing power to the in-vehicle communication device, and the power connect can be any connection capable of transferring the power from the power source to the in-vehicle communication device. According to an embodiment, the power source is a component of the vehicle, and thus the power connect receives power from the component of the vehicle. According to one non-limiting embodiment, the power source is a 12v power source providing 12v of power to the in-vehicle communication device 100.

According to an embodiment, the in-vehicle communication device 100 comprises a ground connect 120. The ground connect can be any ground connection between the in-vehicle communication device and the vehicle. According to an embodiment, the ground connect is connected to a ground relative to the vehicle.

According to an embodiment, the in-vehicle communication device 100 comprises a signal input interface 130. The signal input interface is any interface capable of receiving signals 140 from the vehicle. The signals are vehicle indication signals 140, each indicative of a status of the vehicle in which the device is installed. The signals are received—via wired and/or wireless communication—from one or multiple signal outputs from the vehicle. For example, the signal input interface 130 can be wired to a signal output from the vehicle.

According to an embodiment, there are a plurality of vehicle indication signals. Among many other possibilities, the plurality of vehicle indication signals can be one or more of: (1) a left turn indication signal indicating that the left turn signal is activated; (2) a right turn indication signal indicating that the right turn signal is activated; (3) an ignition signal indicating that the ignition is on; (4) a lightbar indication signal indicating that a lightbar is activated; and (5) a park signal indicating that the vehicle is or is not in park. Many other possible vehicle indication signals are possible.

According to an embodiment, the in-vehicle communication device 100 comprises an N-channel MOSFET bank 150, comprising a plurality of N-channel MOSFETs. According to an embodiment, a MOSFET (metal-oxide-semiconductor field-effect transistor) is a field-effect transistor and comprises an insulated gate where the voltage determines the conductivity of the transistor. Accordingly, the amount of voltage is used for switching electronic signals as described or otherwise envisioned herein.

The N-channel MOSFET bank 150 is in communication with the signal input interface 140, and each of the plurality of N-channel MOSFETs in the N-channel MOSFET bank 150 is connected to a respective one of the plurality of different vehicle indication signals via the signal input interface. Thus, each of the plurality of N-channel MOSFETs is configured to generate an output signal in response to receiving a vehicle indication signal.

Thus, according to an example, the left turn signal is activated either manually or automatically and a left hand signal activation signal is communicated to the signal input interface 140, which is in turn communicated to the N-channel MOSFET in the N-channel MOSFET bank 150 responsible for monitoring left hand signals. According to an embodiment, an N-channel MOSFET holds its respective output to ground (e.g., low) until it is triggered by the vehicle input (e.g., the left hand signal activation signal), at which point it provides an output (e.g., high). The output can be a voltage, for example, of 10v-14v, although other voltages and outputs are possible.

According to an embodiment, the in-vehicle communication device 100 comprises a plurality of LEDs 160. The plurality of LEDs can be any LEDs capable of communicating with light. Thus, the LEDs can be any color, any pattern, any other configuration to communication information with light, including a simple on/off configuration. According to another embodiment, component 160 is a communication or indication method or system other than LEDs. For example, component 160 can be any visible light communication method or system, an audible communication method or system, or any other communication method or system.

According to an embodiment, each of the plurality of LEDs is in communication with a respective one of the plurality of different vehicle indication signals, via the signal input interface 130. Thus, each of the LEDs is configured to activate (e.g., emit light or emit a specific pattern or intensity or color of light) when a vehicle indication signal is received. Additionally or alternatively, each of the LEDs is configured to activate (e.g., emit light or emit a specific pattern or intensity or color of light) whenever the LED is successfully connected to the signal input interface 130 and thus capable of receiving a vehicle indication signal.

Thus, according to an example, the left turn signal is activated either manually or automatically and a left hand signal activation signal is communicated to the signal input interface 140, which is in turn communicated to the LED configured to activate or otherwise responsible for activating when the left hand signal activation signal is received. This activates the LED or changes the LED (e.g., intensity, color, pattern) to emit information that the a left hand signal activation signal is received.

According to an embodiment, the in-vehicle communication device 100 comprises a P-Channel MOSFET 170 connected to a vehicle park indication signal received from the vehicle, such as via the signal input interface 130. The vehicle park indication signal indicates that the vehicle is or is not in park. According to an embodiment, the P-Channel MOSFET is configured to generate an activation signal when the park indication signal indicates that the vehicle is not in park, although other configurations are possible. Thus, the P-Channel MOSFET 170 can be configured to be enabled when the vehicle provides a negative (−) park signal (indicating that the vehicle is not in park). The P-Channel MOSFET 170 can be configured to be hold its output to ground (low) until it is triggered by receiving a negative (−) park signal (indicating that the vehicle is not in park) from the vehicle, such as via the signal input interface 130.

According to an embodiment, if the switch is in position for positive park input, the signal is sent to the designated MOSFET on the N-Channel MOSFET bank. When the switch is in position for negative park, the system utilizes the P-Channel MOSFET.

According to an embodiment, therefore, the in-vehicle communication device 100 can comprise a switch 172 which adjusts for the vehicle park input received from the vehicle. For example, the switch allows the installer to easily configure for either a negative (−) park input from the vehicle or a positive (+) input from the vehicle. The installer can use the switch to select the input from the vehicle, once it is identified. Thus the park switch 172 is configured to adjust between a negative vehicle park indication signal and a positive vehicle park indication signal for the P-Channel MOSFET.

Although FIG. 1 shows the vehicle park input 142 being received from the vehicle via a wired and/or wireless connection. However, according to another embodiment, the vehicle park input 142 is received via the signal input interface 130.

According to an embodiment, the in-vehicle communication device 100 comprises a signal output interface 180. The signal output interface is configured to receive an output signal from the N-channel MOSFET bank and communicate an output signal 190 to a communications interface of a wireless communication device. The wireless communication device can be any device configured to communication information received from the in-vehicle communication device to a remote device or system. For example, the wireless communication device can be a cellular modem that communicates vehicle information—e.g., any of the information described or otherwise envisioned herein—to a remote device or system, such as a cloud-based service or system among other possible remote devices or systems.

According to an embodiment, the signal output interface 180 also receives the activation signal from the P-Channel MOSFET, indicating that the vehicle is not in park. The signal output interface 180 is configured to communicate an output signal 190 to the communications interface of the wireless communication device. According to one embodiment, the signal output interface 180 is configured to communicate the output signal to the communications interface of the wireless communication device only when there is the activation signal from the P-Channel MOSFET.

According to an embodiment, the in-vehicle communication device 100 comprises a housing (not shown) which houses some or all of the components of the device. For example, the housing can partially or wholly encompass the signal input interface, the N-channel MOSFET bank, the plurality of LEDs, the P-Channel MOSFET, and the signal output interface. According to an embodiment, however, the housing comprises an opening (e.g., holes, panel, transparent window, etc.) to communicate light from an activated LED, from the interior of the housing to outside the housing. The housing can be composed of any material suitable for housing, including but not limited to plastic, metal, and other compounds

According to an embodiment, the in-vehicle communication device 100 comprises a plurality of voltage regulators (not shown in FIG. 1). The voltage regulators are configured to, among other possibilities: (i) receive an output signal from the N-channel MOSFET bank; (ii) convert the received output signal to an LED input signal for a respective one of the plurality of LEDs; and (iii) communicate the LED input signal to the respective one of the plurality of LEDs. According to an embodiment, each of the plurality of voltage regulators can be configured to convert the received output signal to a 3-volt LED input signal, although other voltages are possible.

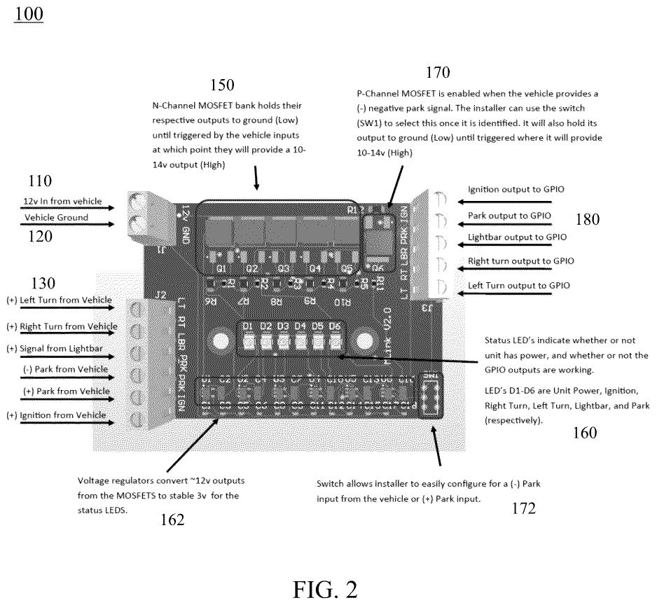

Referring to FIG. 2, in one embodiment, is a schematic representation of an in-vehicle communication device 100 configured to interface between a vehicle and a cellular modem. The devices and systems described in connection with the figures are provided as examples only, and shall be understood to not limit the scope of the disclosure. The in-vehicle communication device can be any of the systems or devices described or otherwise envisioned herein. The in-vehicle communication device can be a single device or multiple devices.

According to an embodiment, the in-vehicle communication device 100 comprises a power connect 110. The power connect can be any connection between the in-vehicle communication device and a power source (not shown), configured to provide power from the power source to the in-vehicle communication device. According to an embodiment, the in-vehicle communication device 100 comprises a ground connect 120. The ground connect can be any ground connection between the in-vehicle communication device and the vehicle.

According to an embodiment, the in-vehicle communication device 100 comprises a signal input interface 130. The signal input interface is any interface capable of receiving signals 140 from the vehicle. The signals are vehicle indication signals 140, each indicative of a status of the vehicle in which the device is installed.

According to an embodiment, the in-vehicle communication device 100 comprises an N-channel MOSFET bank 150, comprising a plurality of N-channel MOSFETs. The N-channel MOSFET bank 150 is in communication with the signal input interface 140, and each of the plurality of N-channel MOSFETs in the N-channel MOSFET bank 150 is connected to a respective one of the plurality of different vehicle indication signals via the signal input interface. Thus, each of the plurality of N-channel MOSFETs is configured to generate an output signal in response to receiving a vehicle indication signal.

According to an embodiment, the in-vehicle communication device 100 comprises a plurality of LEDs 160. The plurality of LEDs can be any LEDs capable of communicating with light. Thus, the LEDs can be any color, any pattern, any other configuration to communication information with light, including a simple on/off configuration. According to an embodiment, each of the plurality of LEDs is in communication with a respective one of the plurality of different vehicle indication signals, via the signal input interface 130. Thus, each of the LEDs is configured to activate (e.g., emit light or emit a specific pattern or intensity or color of light) when a vehicle indication signal is received.

According to an embodiment, the in-vehicle communication device 100 comprises a P-Channel MOSFET 170 connected to a vehicle park indication signal received from the vehicle, such as via the signal input interface 130. The vehicle park indication signal indicates that the vehicle is or is not in park. According to an embodiment, the P-Channel MOSFET is configured to generate an activation signal when the park indication signal indicates that the vehicle is not in park, although other configurations are possible. According to an embodiment, therefore, the in-vehicle communication device 100 comprises a switch 172 which adjusts for the vehicle park input received from the vehicle.

According to an embodiment, the in-vehicle communication device 100 comprises a signal output interface 180. The signal output interface is configured to receive an output signal from the N-channel MOSFET bank and communicate an output signal 190 to a communications interface of a wireless communication device. According to an embodiment, the signal output interface 180 also receives the activation signal from the P-Channel MOSFET, indicating that the vehicle is not in park. The signal output interface 180 is configured to communicate an output signal 190 to the communications interface of the wireless communication device.

According to an embodiment, the in-vehicle communication device 100 comprises a plurality of voltage regulators 162. The voltage regulators are configured to, among other possibilities: (i) receive an output signal from the N-channel MOSFET bank; (ii) convert the received output signal to an LED input signal for a respective one of the plurality of LEDs; and (iii) communicate the LED input signal to the respective one of the plurality of LEDs.

As will be appreciated by one skilled in the art, aspects of the present invention may be embodied/implemented as a computer system, method or computer program product. The computer program product can have a computer processor or neural network, for example, that carries out the instructions of a computer program. Accordingly, aspects of the present invention may take the form of an entirely hardware embodiment, an entirely software embodiment, and entirely firmware embodiment, or an embodiment combining software/firmware and hardware aspects that may all generally be referred to herein as a “circuit,” “module,” “system,” or an “engine.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction performance system, apparatus, or device.

The program code may perform entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The flowcharts/block diagrams in the Figures illustrate the architecture, functionality, and operation of possible implementations of systems, methods, and computer program products according to various embodiments of the present invention. In this regard, each block in the flowcharts/block diagrams may represent a module, segment, or portion of code, which comprises instructions for implementing the specified logical function(s). It should also be noted that, in some alternative implementations, the functions noted in the block may occur out of the order noted in the figures. For example, two blocks shown in succession may, in fact, be performed substantially concurrently, or the blocks may sometimes be performed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While various embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific embodiments described herein. It is to be understood that the foregoing embodiments are presented by way of example only and that, within the scope of the appended claims and equivalents thereto, embodiments may be practiced otherwise than as specifically described and claimed. Embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

What is claimed is:

1. An in-vehicle communication device, comprising:
a power connect;
a ground connect;
a signal input interface configured to receive a plurality of different vehicle indication signals, each of the plurality of vehicle indication signals indicative of a status of a vehicle;
an N-channel MOSFET bank in communication with the signal input interface and comprising a plurality of N-channel MOSFETs, each of the plurality of N-channel MOSFETs connected to a respective one of the plurality of different vehicle indication signals, wherein each of the plurality of N-channel MOSFETs is configured to generate an output signal in response to receiving a vehicle indication signal;
a plurality of LEDs, each of the plurality of LEDs in communication with a respective one of the plurality of different vehicle indication signals, wherein each of the plurality of LEDs is configured to activate in response to receiving a vehicle indication signal; and
a signal output interface configured to receive an output signal from the N-channel MOSFET bank and communicate the output signal to a communications interface of a wireless communication device, wherein the signal output interface is configured to communicate the output signal to the communications interface of the wireless communication device.

2. The in-vehicle communication device of claim 1, further comprising a P-Channel MOSFET connected to a vehicle park indication signal, the vehicle park indication signal indicative that the vehicle is or is not in park, wherein the P-Channel MOSFET is configured to generate an activation signal when the park indication signal indicates that the vehicle is not in park, further wherein the signal output interface is configured to receive the activation signal from the P-Channel MOSFET.

3. The in-vehicle communication device of claim 2, wherein the signal output interface is configured to communicate the output signal to the communications interface of the wireless communication device only when there is the activation signal from the P-Channel MOSFET.

4. The in-vehicle communication device of claim 2, further comprising:
a park switch, the park switch configured to adjust between a negative vehicle park indication signal and a positive vehicle park indication signal for the P-Channel MOSFET.

5. The in-vehicle communication device of claim 1, wherein the plurality of different vehicle indication signals comprise one or more of a left turn indication signal, a right turn indication signal, an ignition signal, and a lightbar indication signal.

6. The in-vehicle communication device of claim 1, wherein the plurality of LEDs comprise one or more of a power LED, a left turn indication signal LED, a right turn indication signal LED, an ignition signal LED, a lightbar indication signal LED, and a park LED.

7. The in-vehicle communication device of claim 1, further comprising:
a housing configured to at least partially house at least the signal input interface, the N-channel MOSFET bank, the plurality of LEDs, and the signal output interface, wherein the housing comprises an opening to communicate an activated LED.

8. The in-vehicle communication device of claim 1, wherein the wireless communication device is a modem.

9. The in-vehicle communication device of claim 1, further comprising:
a plurality of voltage regulators each configured to: (1) receive an output signal from the N-channel MOSFET bank; (ii) convert the received output signal to an LED input signal for a respective one of the plurality of LEDs; and (iii) communicate the LED input signal to the respective one of the plurality of LEDs.

10. The in-vehicle communication device of claim 7, wherein each of the plurality of voltage regulators converts the received output signal to a 3-volt LED input signal.
